(19) United States
(12) Patent Application Publication
(10) Pub. No.: US 2008/0071483 A1
(43) Pub. Date: Mar. 20, 2008

(54) Battery health monitor

(76) Inventor: Stephen Spencer Eaves, Charlestown, RI (US)

Correspondence Address: Stephen S. Eaves, 9 General Stanton Lane, Charlestown, RI, 02813, US

(21) Appl. No.: 11/584,982

(22) Filed: Oct. 23, 2006

Related U.S. Application Data
(60) Provisional application No. 60/730,190, filed on Oct. 26, 2005.

(51) Int. Cl. G01R 31/36

(52) U.S. Cl. 702/63; 429/90

(57) ABSTRACT

A device is disclosed for providing information related to the state of health of rechargeable batteries. The device (10) permanently attaches to the battery and measures key parameters such as battery current, voltage and temperature. Using this information, the device can derive information on the general age and health of the battery. A unique feature is the ability to use any common conductor in series with the battery cells as a current measuring shunt, even if the exact characteristics of the conductor are unknown. Thus the need for a calibrated current shunt or other current measuring sensor is eliminated.

### CLAIM OF PRIORITY

This application claims priority to U.S. Ser. No. 60/730,190 entitled “Battery Health Monitor” filed on Oct. 25, 2005, naming Stephen Eaves of Charlestown, R.I. as inventor, the contents of which are herein incorporated by reference in their entirety.

### FIELD OF INVENTION

The invention relates generally to a device multi-cell battery health monitoring. More specifically the invention relates to battery monitoring devices that permanently attached to a battery and provide a continuous assessment of battery age and health.

### BACKGROUND

In the field of rechargeable batteries, it is often useful to have a measure of the age and health of a battery. The information provides for better planning when preparing to use or service a battery. The information can be extremely valuable when a battery is used as part of an emergency back-up system such as employed in most telecommunication systems or in a life support system such as used in underwater vehicles.

One common application for the proposed invention is in the field of batteries for motive power, such as lift trucks or floor sweepers. These vehicles have a removable battery. When the battery is depleted of energy it is typically exchanged with another fully charged battery. The proposed device would permanently mount to each battery and remain attached for the life of the battery.

If the general condition of the battery is known, an operator may plan in advance for upcoming repairs, or more importantly, remove the battery from service before it fails to perform its designated function.

A very common indicator of battery usage is a count representing the total number of times the battery has been charged and discharged. This type of measurement does not provide a total indication of the health of the battery, but is a generally accepted indicator, analogous to an odometer on an automobile.

By combining cycle count with depth of discharge and battery temperature, a more accurate indication of battery health can be derived. This generally requires testing or manufacturer data on cycle life versus depth of discharge at various temperatures. As a guideline, it is generally known in the industry that the life of a lead-acid battery is halved for every 10° C. increase in operating temperature.

Another useful indicator of health is coulumbic efficiency, that is, a ratio of discharge energy to charge energy. coulumbic efficiency is affected by charge/discharge rate, battery age and temperature. If the usage pattern of a battery is generally known, a change in coulumbic efficiency is a good indicator of a change in the health of the battery.

When constructing a battery string, a number of individual cells are combined in series. The cell connections are made using intercell connectors. In many motive power batteries, the intercell connectors are made from Lead. In many telecommunication batteries, the interconnections are made from copper bars, straps or cables. When current flows through the string during charge or discharge, there is a small voltage drop along the length of the intercell connector. Using the appropriate methods described below, this voltage drop can be used as an indicator of battery current By integrating the current with time over consecutive charge and discharge cycles, a calculation of coulumbic efficiency can be made.

### BRIEF DESCRIPTION OF THE DRAWINGS

FIG. 1 depicts the Battery Health Monitor attached to a battery intercell connector.

FIG. 2 shows a block diagram of the Battery Health Monitor depicting its major components.

### DESCRIPTION OF THE INVENTION

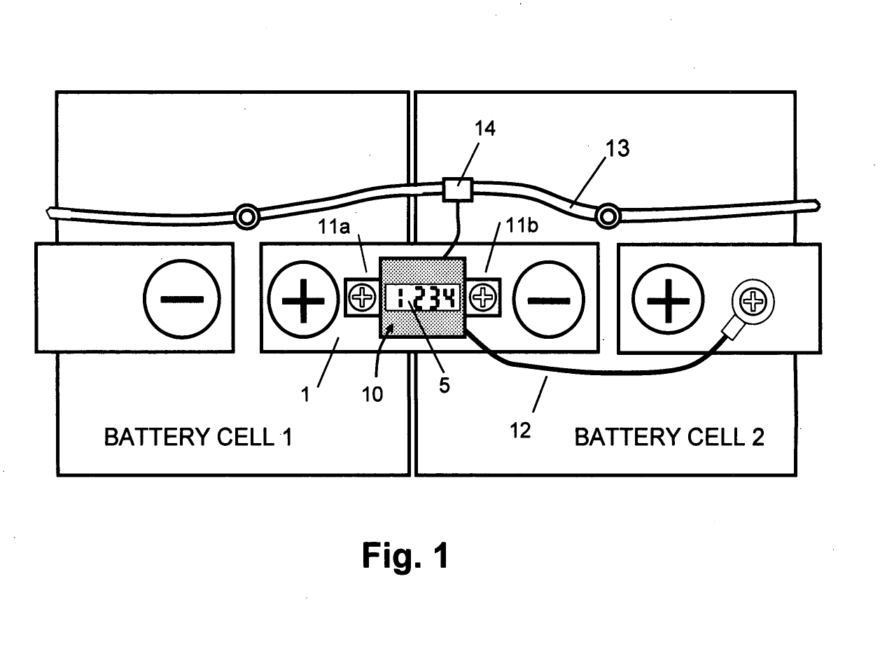

In the preferred embodiment, the Battery Health Monitor 10 is permanently attached to a battery intercell connector 1 as depicted in FIG. 1. Metal tabs 11a, 11b are attached via screws to the surface of the intercell connector. The attachments preferably serve as both mechanical and electrical connections to the device. A liquid crystal display 5, is provided as a means to communicate the battery health information to the user. When electrical current is passing through the intercell connector, a small voltage will appear between tabs 11a, 11b. This voltage drop is equal to the battery current multiplied by the electrical resistance between the two points. The voltage drop is referred to as the “current signal”. The polarity of the voltage drop reverses as the current reverses from charge to discharge. Because the exact resistance of the intercell connector may not be known to the Health Monitor, the exact value of current can not be obtained without outside calibration. However, it will be shown that knowing the exact current value is not critical to the device's ability to provide basic information on the operating condition of the battery. Thus the device can be easily attached to the battery and begin operation without the requirement for user calibration.

Many motive power batteries that use flooded lead-acid cells utilize commercially available, automatic watering systems. These systems comprise a plastic watering line 13 that distributes water to an inlet port on each cell. It is useful to record when an operator has activated the watering system and to combine this data with other Health Monitor information, such as the temperature of the battery when the watering occurred. The Health Monitor is equipped with an optional capability to monitor the flow of water in the line using a suitable flow sensing means 14. In the preferred embodiment a commercially available pressure switch is used to provide a flow signal to the Health Monitor.

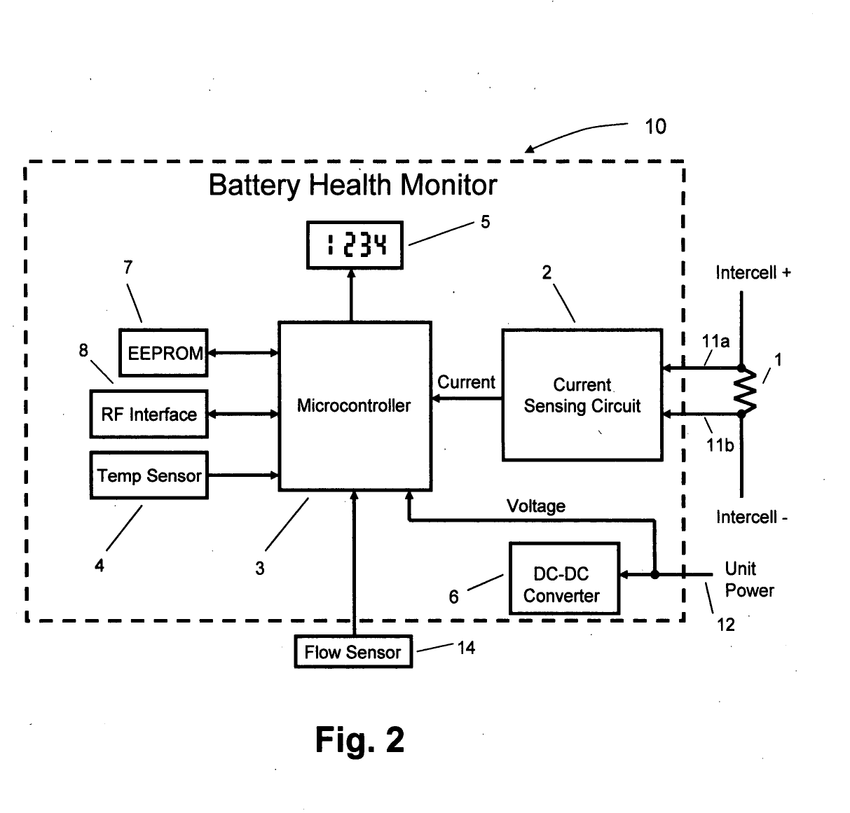

Referring to the block diagram of FIG. 2, the voltage drop across the intercell connector is amplified by current signal conditioning circuit 2. The amplified current signal is fed to an analog to digital converter input of microcontroller circuit 3.

The health monitor is preferably powered by an internal DC-DC converter 6 that transforms the voltage range of a battery cell or cells to the internal regulated supply voltage used by the health monitor. Power lead 12 connects the DC-DC converter to an adjacent cell on the battery. Stated another way, the DC-DC converter sees the potential between power lead 12, and tabs 11a, 11b as its supply voltage and creates a regulated output voltage for the Health Monitor internal components. Power lead 12 and tabs 11a, 11b are shown figuratively in FIG. 1 and functionally in FIG. 2. The power lead is also internally connected to microcontroller 3 shown in FIG. 2 for use in measuring the voltage between tabs 11a, 11b and the point that power lead 12 attaches to. This measurement will be referred to later when discussing cycle counting and state-of-charge measurement

If the watering system flow sensing option is utilized, the signal from flow sensor 14 is provided to the microcontroller for logging.

Cycle Counting

A cycle count represents the combinational occurrence of charge and discharge. This may be detected by sensing a reversal in current flow through the battery. It is useful to filter the current signal when cycle counting to require a minimum magnitude and duration of current when counting a cycle. The filter can be implemented using a combination of analog circuitry in the current sensing circuit 2 and digital filtering in the microcontroller. This will separate the current reversal from electrical noise, charger ripple currents or short “regeneration” pulses that occur in some traction motor controllers when a vehicle decelerates.

As an additional cycle count calculation variable, the rise and fall of the voltage between tabs 11a, 11b to another point in the series battery string that power lead 12 is attached to can be used in detecting a cycle count, preferably in combination with the current measurement method described above.

As discussed above, a cycle count is only a general indicator of battery usage similar to an automobile odometer. The cycle count, as a raw value, does not take into account how abusive the conditions were when the cycle occurred. In any case, the cycle count is an industry accepted indicator of battery usage and is one of the values presented on the counter Liquid Crystal Display (LCD) identified as reference numeral 5 of FIG. 2.

State of Charge

By combining the voltage reading from power line 12 with the current reading, a relatively accurate State-of-Charge calculation can be made. The calculation is based on a method generally known to the industry that combines a time-integrated current measurement, a voltage measurement, and historical information from previous cycles. This is generally described by the formula:
SoC=ƒ₁(V,T,I)+ƒ₂(Cᵣ,∫I dt,H_{c})
Where:

SoC is the state-of -charge of the battery.

ƒ₁(V,T) is a function with the variables cell voltage (V), cell temperature (T) and cell current (I). The function is a predetermined mathematical formula or processor look-up table based on known characteristics of the battery chemistry typically provided by the battery manufacturer.

ƒ₂(Cr,∫I dt) is a function that combines the rated capacity of the cell (Cᵣ) with the time integrated current reading (∫I dt,H_{c}) and historical data (H_{c}) containing stored values of capacities achieved on previous charge and discharge cycles under similar conditions. It should be noted that the value of Cᵣ may not always be known if the user chooses not to perform a calibration procedure on the health monitor. In this case, the device would initially rely on only ƒ₁(V,T) until some initial charge/discharge cycles were recorded by the device. After some historical data is recorded the health monitor will create its own assumed value for Cᵣ.

Coulumbic Efficiency

As discussed above, Coulumbic Efficiency is the ratio of discharge energy to charge energy. Microcontroller 3 will accumulate current readings to produce a value representing the total coulomb count during charge and discharge. Since only the ratio of the charge to discharge count is necessary to calculate the efficiency, the exact magnitude of current passing through the battery is not required. Thus it is not necessary to calibrate or know the exact resistance of intercell connector 1 to operate the Health Monitor. The efficiency value is one of the values presented on the counter LCD 5 of FIG. 2.

Data Logging, Communication Interface and Calibration

The Health Monitor will have the ability to maintain a record of the parameters that it monitors. This includes the current signal, local temperature as obtained by temperature sensor 4 of FIG. 2 and time. A limited amount of data can be maintained in internal memory. External EEPROM memory 7 is used for long term storage for Health Monitor recorded data. The microcontroller has the ability to average the data parameters over a predetermined time period and store the values at the end of each period, thus conserving memory space.

An optional communication interface is used to retrieve logged data In the preferred embodiment, a Radio Frequency (RF) interface 8 is employed. Optional Health Monitor interface software that can be installed in an external computer can guide the user through a calibration procedure that asks the user to charge or discharge the battery at a known current. The Health Monitor will then measure the voltage drop detected on the intercell connector at the known current value. Once the current value is entered by the user, the Health Monitor will calculate the resistance of the intercell connector by Ohms Law; or Resistance=Voltage/Current.

The interface software allows the user to enter specifics regarding the battery such as capacity, age and specifics about the battery chemistry. Even the type of metal that the intercell connector is constructed from may be entered to allow temperature compensation of the intercell connector resistance. The calibration data is stored in the Health Monitor and need not be entered again until the next calibration period, perhaps a yearly occurrence.

Once the Health Monitor is calibrated and the battery specifics are entered, the current, temperature and time data can be used to provide a history of battery usage. More advanced health prediction algorithms can also be executed by the interface software.

Although the data interface offers many advanced features, many users may prefer to not pay for the options and use the Health Monitor as a simple device where cycle count, coulombic efficiency and error codes are provided directly by the LCD display. As discussed the exact intercell connector resistance is not needed for basic operation.

Error Messages and Warnings

The health monitor can display error messages and warnings of anomalous operation or damaging conditions. For example, erratic voltage readings may indicate a poor connection of the Health Monitor to the intercell connector or the device may display a warning of high operating temperature.

Integration to a Charger or Battery Management System

Using the wireless interface, the Health Monitor can be accessed by an external charger. The charger may request battery temperature, cycle count, coulombic efficiency or other data in order to optimize its charge profile. A unique identification number contained in the Health Monitor allows the battery to be identified by referencing user entered information keyed to the ID number. The Health monitor may serve as part of a complete battery management system that records the status of the battery as the Health Monitor passes within range of a wireless receiver connected to the battery management system. The battery management system may also consist of a networked set of chargers that communicate to a number of Health Monitors.

Summary, Ramifications and Scope

From the above description it can be seen that the disclosed invention offers a convenient and useful means for managing a battery and avoiding unexpected failure of a battery powered system. The device offers the convenience of easy installation without a requirement for calibration, or optionally, more advanced features through the use of a communication interface. This disclosure offers a preferred embodiment of the device but is not meant to narrowly limit the scope of the invention. The circuitry used to perform the described functions could have a number of ramifications. For example, a Field Programmable Gate Array (FPGA) could replace the microcontroller, or a single integrated circuit could combine some of the analog and digital functions described.

Current sensing circuit 2, could be replaced with a monolithic integrated circuit that amplifies the current signal and converts it to digital form before providing it to the microcontroller.

Rather than using DC-DC converter 6, an alternative implementation could power the Health Monitor from an internal battery. This would preferably be a Lithium primary battery that can support 3-5 years of operation.

The communication interface could be implemented using optical or conductive means. When a communication interface is included, there may be versions of the Health Monitor that do not include display 5 in order to reduce the physical volume and cost of the unit.

I claim:

1. A device for recording information pertaining to the operating condition of a multi-cell rechargeable battery comprising:
voltage drop sensing means for measuring the voltage drop across a length of a conductor electrically in series with the battery cells where said voltage drop is proportional to the battery current,
processing means for relating patterns in the value of said battery current to at least the battery charge cycles and coulumbic efficiency,
communication means for communicating the at least charge cycles and coulumbic efficiency to an external entity.

2. The device according to claim 1 further including a temperature sensing means for the measurement of said battery temperature.

3. The device according to claim 1 wherein said device is powered by a plurality of cells from said battery.

4. The device according to claim 1 wherein said device is powered by its own internal battery rather than from the battery that is being monitored.

5. The device according to claim 1 wherein said communication means comprises a liquid crystal display for displaying information to a human entity.

6. The device according to claim 1 wherein said communication means comprises a radio frequency circuit means for exchange of data to and from an external electronic entity.

7. The communication means according to claim 6 wherein said radio frequency circuit means is used to transfer configuration data from said external electronic entity to said device.

8. The device according to claim 1 further including cell voltage sensing means for measuring the voltage across at least one cell of said battery and for utilizing the cell voltage in conjunction with said current as a variable in the determination of said charge cycles.

9. The device according to claim 1 further including cell voltage sensing means for measuring the voltage across at least one cell of said battery and for utilizing the cell voltage in conjunction with said current as a variable in estimating the state-of-charge of said battery.

10. The device according to claim 1 further including means for storing a unique identification number that can be provided to said external entity through said communications means for the purpose of identifying said battery.

11. The device according to claim 1 further including flow sensing means for sensing water flow in an existing battery watering system such that a watering event can be detected and recorded within said device.

12. A device for recording information pertaining to the operating condition of a multi-cell rechargeable battery comprising:
Current sensing means for measuring the voltage drop produced across a length of conductor in series with the battery cells where said voltage drop is proportional to the current flowing through said conductor,
processing means for relating polarity reversals in said battery current to its number of charge/discharge cycles and for relating the ratio of time integrated current measurements during charge and discharge to coulumbic efficiency,
communication means for communicating the at least charge cycles and coulumbic efficiency to an external entity.

13. The device according to claim 12 further including a temperature sensing means for the measurement of said battery temperature.

14. The device according to claim 13 wherein said processing means is configured to detect battery abuse due to an operating temperature that is higher than a predetermined value.

15. The device according to claim 12 wherein said device is powered by a plurality of cells from said battery.

16. The device according to claim 12 wherein said processing means is configured to detect an impending failure of said battery due to a drop in said coulumbic efficiency below a predetermined value.

17. The device according to claim 12 wherein said communication means comprises a radio frequency circuit means for exchange of data to and from an external electronic entity.

18. The communication means according to claim 17 wherein said external electronic entity is a battery charger.

19. The device according to claim 12 further including cell voltage sensing means for measuring the voltage across at least one cell of said battery and for utilizing the cell voltage in conjunction with said current as a variable in the determination of said charge cycles.

20. The device according to claim 12 further including cell voltage sensing means for measuring the voltage across at least one cell of said battery and for utilizing the cell voltage in conjunction with said current as a variable in estimating the state-of-charge of said battery.
